(19) United States
(12) Patent Application Publication
(10) Pub. No.: US 2002/0115001 A1
(43) Pub. Date: Aug. 22, 2002

(54) Electrostatic discharge effect free mask

(76) Inventors: Chen-Chiu Hsue, Hsinchu (TW); Cheng-Hui Chung, Hsinchu Hsien (TW); Yei-Hsiung Lin, Hsinchu (TW)

Correspondence Address: Victor Flores, LARIVIERE, GRUBMAN & PAYNE, LLP, P. O. Box 3140, Monterey, CA, 93942, US

(21) Appl. No.: 09/792,380

(22) Filed: Feb. 21, 2001

(51) Int. Cl. G03F 9/00; G03C 5/00; B32B 17/06; B32B 17/10

(52) U.S. Cl. 430/5; 430/322; 430/324; 428/426; 428/441

(57) ABSTRACT

The present invention discloses an electrostatic effect free mask. The mask is made by depositing a layer of slightly conductive and transparent polymer onto a mask. The present invention can prevent adjacent patterns from point to point discharging during processes, and thus maintain the integrity of the mask.

### BACKGROUND OF THE INVENTION

1. Field of the Invention

The present invention relates to an electrostatic discharge (ESD) effect free mask, in particular, to a mask coated with a layer of polymer that is slightly conductive and transparent to prevent patterns of the circuit on the mask from being damaged by the ESD effect.

2. Description of Related Art

FIG. 1 is a cross-sectional view of a conventional mask. The main body of the mask is made from a flat and transparent SiO₂ glass 10. A semiconductor circuit pattern is formed by coating a layer of chrome film 11 with thickness of several hundred angstroms on the surface of said glass 10. Sometimes, processing engineer will further coat a layer of chrome oxide film 12 on the surface of said chrome film 11 to prevent the reflection phenomena of the chrome film 11 during the process of exposure.

During the process, electrostatic charges will accumulate on the surface of mask as time goes on. When electrostatic charges accumulate to a certain level, it has to find a way to vent. Under such a circumstance, normally electrostatic charge will lead off from the nearest corners between two adjacent patterns, especially corners between two larger patterns, by point-to-point discharging to release electrostatic charge, just like the two adjacent chrome films 11 of patterns that induce ESD effect shown in FIG. 2. Unfortunately, the heat produced at the instant of discharge is huge enough to damage circuit patterns and thus make the yield decrease. In an extreme case, it will even cause the mask to break down.

The point-to-point discharging phenomenon described above is even more serious as a mask manufacturing process develops towards a narrower line width.

A conventional method for solving this problem is to link the closest corners of any two adjacent patterns of a mask 20 with a thin conducting wire 21, as shown in FIG. 2, and further link the wire 21 to a grounding end (not shown) to avoid the accumulation of electrostatic charges which results in an ESD effect. However, the shortcoming of this method is that the conducting wire could be exposed together with patterns of the chrome film 11 on the photo resist to form a latent figure and then appear after a development process. This will change the semiconductor pattern and make the process to fail.

### SUMMARY OF THE INVENTION

A main object of the present invention is to provide a mask that is able to avoid an electrostatic discharge effect, so as to prevent a mask from being damaged due to a discharging phenomena coming from the accumulation of electrostatic charges.

To overcome the shortcoming of prior art and achieve the object mentioned above, the present invention provides an electrostatic discharge free mask comprising a substrate, a chrome film, and a polymer layer. The chrome film is located on the surface of the substrate to represent a pattern of circuit. The polymer layer is deposited on the surface of the substrate and chrome film, which is slightly conductive and transparent.

By depositing a polymer layer on the surface of the mask, the breakdown of the mask due to ESD effect can be prevented.

### BRIEF DESCRIPTION OF THE DRAWINGS

In the accompanying drawings:

FIG. 1 is a cross-sectional view of a conventional mask;

FIG. 2 is a front view of a conventional mask;

FIG. 3 is a cross-sectional view of a mask according to the present invention; and

FIG. 4 is a frontview of a mask according to the present invention.

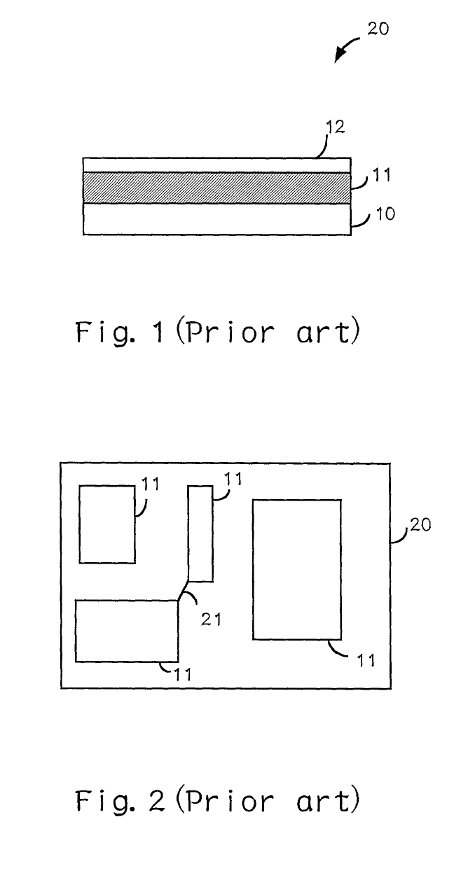

### DETAILED DESCRIPTION OF THE INVENTION

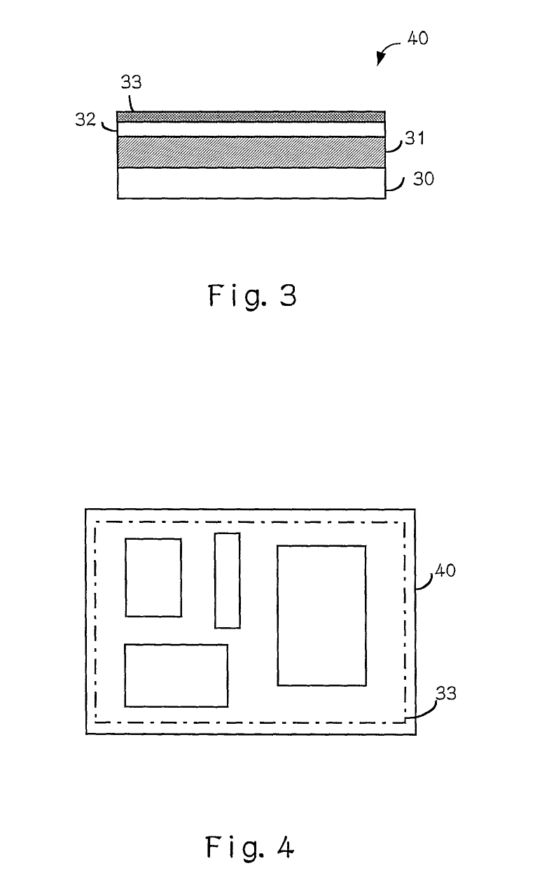

FIG. 3 is a cross-sectional view of a mask according to the present invention. The mask contains a substrate 30 (such as SiO₂ glass), a chrome film 31, a layer of chrome oxide film 32, and a layer of conductive polymer 33 in sequence from bottom to top.

The chrome film 31 is made by depositing a layer of metallic chrome with thickness of several hundred angstroms on the surface of the substrate 30, and it is used to form a the pattern of semiconductor circuit. The chrome oxide film 32 can be added optionally to prevent the reflection phenomena of the chrome film 31 during exposure. The polymer layer 33 is one of characteristics of the present invention. The purpose of the polymer layer is to prevent two adjacent patterns from electrostatic discharging effect and thus from damage to patterns of circuit. The material of the polymer layer 33 has to be transparent to let light passing through to accomplish the exposure. Besides, the polymer layer must be slightly conductive to let electrostatic charges disperse before they accumulates on the surface of the mask 40. This can prevent electrostatic charges from gathering together at some certain areas and eliminate the discharging phenomena later on. However, if the conductivity of the polymer layer being used is too high, the mask 40 will become a conductor, and thus the mask still not suitable for use in photolithography. The range of conductivity of the polymer being used in the present invention is about 50˜2000 Siemens per cm. Materials such as polyacetylene, polypyrrle, polythiophene, polyphenylene, and polyfuran can be used. Some other materials that can be used can be found in C&EN, Dec. 3, 1990, pp. 36-54, by Mercourl G. Kanatzidls, entitled “Conductive Polymers”. The present invention does not set any limitation on this.

FIG. 4 is a front view of the mask of the present invention. There are desired patterns of the circuit on mask 40, and a transparent conductive polymer layer 33 is deposited on the surface of circuit patterns to achieve the effect of dispersing electrostatic charges. Furthermore, the existence of conductive polymer layer 33 will not affect exposure or any other following development processes.

The technical contents and features of the present invention are disclosed above. However, anyone that is familiar with the technique could possibly make modify or change the details in accordance with the present invention without departing from the technologic ideas and spirit of the invention. The protection scope of the present invention shall not be limited to what embodiment discloses, it should include various modification and changes that are made without departing from the technologic ideas and spirit of the invention, and should be covered by the claims mentioned below.

What is claimed is

1. An electrostatic discharge effect free mask, comprises:
a substrate;
a chrome film deposited on the substrate to form a pattern of circuit; and
a transparent and slightly conductive, polymer layer deposited on the substrate and the chrome film; so as to prevent the mask from being damaged due to electrostatic charge accumulation.

2. The mask according to claim 1, wherein the conductivity of the polymer layer is in the range of 50˜2000 Siemens per cm.

3. The mask according to claim 1, wherein the material of the polymer layer is selected from the group consisting of polyacetylene, polypyrrle, polythiophene, polyphenylene, and polyfuran.

4. The mask according to claim l, further comprising a chrome oxide layer between the chrome film and the polymer layer to prevent the chrome film from a reflection phenomena during exposure.

5. The mask according to claim 1, wherein the substrate is a Sio₂ glass.
